(19) United States
(12) Patent Application Publication
(10) Pub. No.: US 2018/0350653 A1
(43) Pub. Date: Dec. 6, 2018

(54) SUBSTRATE SUPPORTING DEVICE AND SUBSTRATE PROCESSING APPARATUS INCLUDING THE SAME

(71) Applicant: ASM IP Holding B.V., Almere (NL)

(72) Inventors: Sang Jin Jeong, Chungcheongnam-do (KR); Jeung Hoon Han, Gyeonggi-do (KR); Young Seok Choi, Daejeon (KR); Ju Hyuk Park, Chungcheongnam-do (KR)

(21) Appl. No.: 15/985,539

(22) Filed: May 21, 2018

(30) Foreign Application Priority Data
May 30, 2017 (KR) 10-2017-0066979

(51) Int. Cl. H01L 21/687; H01L 21/67; H01L 21/02; H01J 37/32; C23C 16/455; C23C 16/505

(52) U.S. Cl. CPC H01L 21/68735; H01J 2237/2001; H01L 21/02164; H01L 21/02274; H01L 21/0228; H01J 37/32082; H01J 37/3244; H01J 37/32724; H01J 37/32834; H01J 37/32513; C23C 16/45544; C23C 16/505; H01J 2237/332; H01J 2237/3321; H01L 21/67109

(57) ABSTRACT

Provided is a substrate supporting device which prevents intrusion of a process gas into a rear surface of a substrate in a high-temperature process. The substrate supporting device includes a support portion configured to have a line contact with an edge exclusion zone of the substrate that is deformed at a specific temperature.

### CROSS-REFERENCE TO RELATED APPLICATION

This application claims the benefit of Korean Patent Application No. 10-2017-0066979, filed on May 30, 2017, in the Korean Intellectual Property Office, the disclosure of which is incorporated herein in its entirety by reference.

### BACKGROUND

### 1. Field

One or more embodiments relate to a substrate supporting device, for example, a susceptor, and a substrate processing apparatus including the same, and more particularly, to a substrate supporting device which may prevent rear-surface deposition of a substrate to be processed, and a substrate processing apparatus including the same.

### 2. Description of the Related Art

In a semiconductor deposition apparatus, a heater may be generally provided in a reactor to supply heat to a mounted substrate. The heater is referred to as a heater block, and may include a heat wire and a thermocouple (TC). A susceptor is further provided on an upper end of the heater block, and a substrate is substantially mounted on the susceptor in a reaction space. However, when a process is performed at high temperature, the susceptor or the substrate may be deformed due to the high temperature. As a process gas intrudes between the deformed susceptor and the substrate or between the deformed substrate and the susceptor, a rear surface of the substrate may be deposited upon. A film deposited on the rear surface of the substrate may become not only a contamination source in a reactor, but also a contamination source contaminating an apparatus in a subsequent process. Furthermore, the film may deteriorate semiconductor device yield and device properties.

### SUMMARY

One or more embodiments include a substrate supporting device capable of preventing a gas used during a film deposition process from intruding into a rear surface of a substrate and forming a thin film thereon, and a substrate processing apparatus including the same.

Additional aspects will be set forth in part in the description which follows and, in part, will be apparent from the description, or may be learned by practice of the presented embodiments.

According to one or more embodiments, a substrate supporting device includes an inner portion, a periphery portion, and a concave portion formed between the inner portion and the periphery portion wherein a first step portion is formed between the inner portion and the concave portion, and a second step portion is formed between the periphery portion and the concave portion.

The substrate supporting device may further include a rim arranged in the concave portion, wherein the rim is arranged between the first step portion and the second step portion.

The rim may include a third step portion formed on an upper surface of the rim toward the inner portion.

The third step portion may include a pad, and a substrate may be accommodated on the pad.

A height of the first step portion may be lower than a height of the pad such that a lower surface of the substrate is spaced apart from the inner portion.

A height of the third step portion may be lower than an upper surface of the substrate.

The first step portion and the rim may be spaced apart from each other.

A height of the second step portion may be lower than a height of the rim.

The rim may include an insulation body.

The substrate may be accommodated on the rim, the substrate may be deformed at a specific temperature to have a certain curvature toward the inner portion, and a deformed substrate may have a line contact with the rim.

A portion of the rim forming a line contact may have a non-right angle shape.

According to one or more embodiments, a substrate supporting device for accommodating a substrate includes an edge exclusion zone, the substrate support device including a support portion configured to have a line contact with the edge exclusion zone of the substrate deformed at a specific temperature.

When the substrate is accommodated on the support portion at a first temperature, the edge exclusion zone may have a first contact with the support portion.

The substrate may have deformed at a second temperature higher than the first temperature such that an area between the edge exclusion zone and a side surface of the substrate has a second contact with the support portion, and an area where the substrate and the support portion contact each other by the second contact is smaller than an area where the substrate and the support portion contact each other by the first contact.

A surface roughness of a portion of the substrate supporting device forming the line contact may be less than a surface roughness of the other portion of the substrate supporting device.

The substrate supporting device may further include a heating portion arranged spaced apart from the substrate, wherein properties of a thin film formed on the substrate are controlled according to a distance between the substrate and the heating portion.

According to one or more embodiments, a substrate processing apparatus includes a reactor wall, a substrate supporting device, a heater block, a gas inlet unit, a gas supply unit, and an exhaust unit, wherein the reactor wall and the substrate supporting device have a face contact forming a reaction space, and the substrate supporting device includes a susceptor main body and a rim.

The susceptor main body may include an inner portion, a periphery portion, and a concave portion formed between the inner portion and the periphery portion, and the rim may be arranged in the concave portion.

A first space may be formed between the substrate and the inner portion, and a second space may be formed between the inner portion and the rim.

According to one or more embodiments, a substrate processing method for depositing a thin film includes supplying a source gas, supplying a reactive gas, and activating the reactive gas, which are repeated to deposit the thin film, wherein a substrate and a susceptor are spaced apart from each other, and properties of the thin film is controlled according to an interval between a main body of the susceptor and the substrate.

### BRIEF DESCRIPTION OF THE DRAWINGS

These and/or other aspects will become apparent and more readily appreciated from the following description of the embodiments, taken in conjunction with the accompanying drawings in which:

FIG. 1A schematically illustrates a substrate supporting device, for example, a susceptor main body, according to an embodiment;

FIG. 1B is a cross-sectional view of a substrate supporting device taken along a line A-A′ of FIG. 1A;

FIG. 1C schematically illustrates a concave portion of a susceptor main body having a round concave surface;

FIG. 2A schematically illustrates that the susceptor main body and a rim are separated from each other, according to an embodiment;

FIG. 2B illustrates that the susceptor main body and the rim of FIG. 2A are coupled to each other;

FIG. 2C is a cross-sectional view of the substrate supporting device taken along a line B-B′ of FIG. 2B;

FIG. 2D illustrates that the rim is coupled to the concave portion of FIG. 1C;

FIG. 3 is an enlarged view illustrating that the rim is accommodated in the concave portion of the susceptor main body, according to an embodiment;

FIG. 4 is an enlarged cross-sectional view of an area S1 of FIG. 3;

FIG. 5 is an enlarged cross-sectional view of an area S2 of FIG. 3;

FIG. 6 schematically illustrates a substrate including an edge exclusion zone;

FIG. 7 illustrates that the substrate of FIG. 6 is accommodated on a pad, according to an embodiment;

FIG. 8 schematically illustrates that a high-temperature process is performed by using an assembly of FIG. 7;

FIG. 9 is a schematic cross-sectional view of a substrate processing apparatus including a substrate supporting device according to embodiments;

FIGS. 10A and 10B are flowcharts schematically showing substrate processing methods using the substrate processing apparatus, according to other embodiments;

FIGS. 11A, 11B and 11C illustrate a thickness of a SiO₂ film deposited on a rear surface of the substrate when a process is performed by using the substrate processing apparatus of FIG. 9; and

FIG. 12 is a graph showing a change in a wet etch ratio (WER) according to a distance between an inner portion of the susceptor and the substrate when the SiO₂ film is deposited on the substrate by a PEALD method using the susceptor, according to an embodiment.

### DETAILED DESCRIPTION

Embodiments are provided to further completely explain the present inventive concept to one of ordinary skill in the art to which the present inventive concept pertains. However, the present inventive concept is not limited thereto and it will be understood that various changes in form and details may be made therein without departing from the spirit and scope of the following claims. That is, descriptions on particular structures or functions may be presented merely for explaining embodiments of the present inventive concept.

Terms used in the present specification are used for explaining a specific embodiment, not for limiting the present inventive concept. Thus, the expression of singularity in the present specification includes the expression of plurality unless clearly specified otherwise in context. Also, terms such as “comprise” and/or “comprising” may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof. As used in the present specification, the term “and/or” includes any one of listed items and all of at least one combination of the items.

In the present specification, terms such as “first” and “second” are used herein merely to describe a variety of members, parts, areas, layers, and/or portions, but the constituent elements are not limited by the terms. It is obvious that the members, parts, areas, layers, and/or portions are not limited by the terms. The terms are used only for the purpose of distinguishing one constituent element from another constituent element. Thus, without departing from the right scope of the present inventive concept, a first member, part, area, layer, or portion may refer to a second member, part, area, layer, or portion.

Hereinafter, the embodiments of the present inventive concept are described in detail with reference to the accompanying drawings. In the drawings, the illustrated shapes may be modified according to, for example, manufacturing technology and/or tolerance. Thus, the embodiment of the present inventive concept may not be construed to be limited to a particular shape of a part described in the present specification and may include a change in the shape generated during manufacturing, for example.

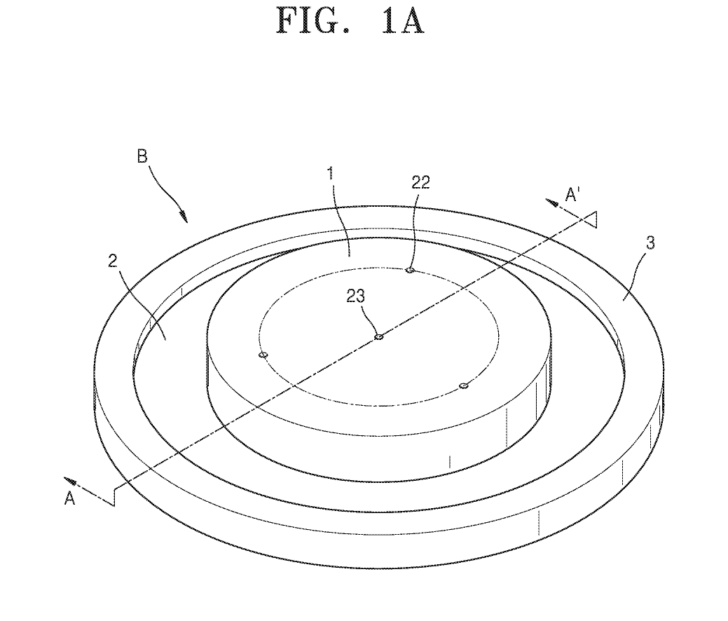

FIG. 1A schematically illustrates a substrate supporting device according to an embodiment. FIG. 1B is a cross-sectional view of a substrate supporting device taken along a line A-A′ of FIG. 1A.

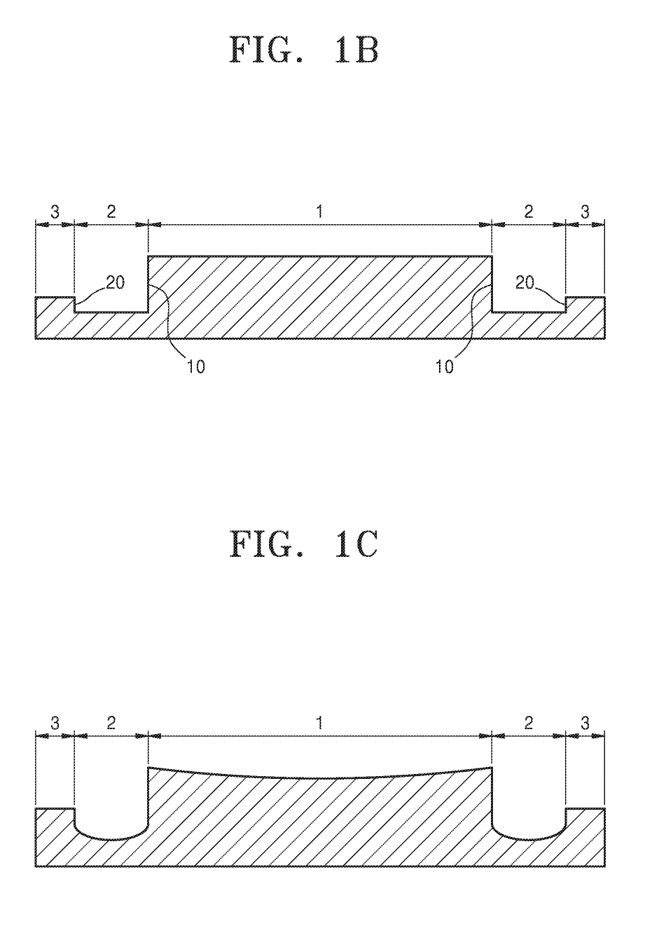

Referring to FIGS. 1A and 1B, the substrate supporting device according to the present embodiment may include a susceptor main body B. The susceptor main body B may include, on one surface thereof, an inner portion 1, a periphery portion 3, and a concave portion 2 formed between the inner portion 1 and the periphery portion 3. As described below, a rim (see FIGS. 2A to 2C) may be arranged in the concave portion 2.

The inner portion 1 and the concave portion 2 form a first step portion 10. The first step portion 10 may be formed between the inner portion 1 and the concave portion 2. The periphery portion 3 and the concave portion 2 form a second step portion 20. The second step portion 20 may be formed between the periphery portion 3 and the concave portion 2. The rim may be arranged between the first step portion 10 and the second step portion 20.

In an embodiment, the susceptor main body B is manufactured in a continuous one part, generally in a circular and disc shape. However, the shape of the susceptor main body B is not limited thereto and the susceptor main body B may have a shape corresponding to the shape of a substrate to be processed. For example, when the substrate to be processed is a rectangular display substrate, the susceptor main body B may have a rectangular shape to accommodate the rectangular substrate.

The susceptor main body B may be adjusted and configured to have a size capable of accommodating a semiconductor substrate having a certain diameter, including a substrate of, for example, 150 mm, 200 mm, and 300 mm. Furthermore, the susceptor main body B may be formed of a metal material such as aluminum or an alloy, or a material having a high thermal conductivity, to smoothly transfer heat to the substrate from a heater block (not shown) that supports the susceptor main body B.

The inner portion 1 may include at least one substrate support pin hole 22 to load and support the substrate. Furthermore, the inner portion 1 may include at least one susceptor main body fixing support pin hole 23 to fix the susceptor main body B to the heater block.

The periphery portion 3 may have a flat surface to form a reaction space by face-contacting and face-sealing a reactor wall of a reactor. The inner portion 1 may have a flat surface to uniformly transfer heat from the heater block toward the substrate.

The structure of the susceptor main body B is not limited to that illustrated in FIGS. 1A and 1B. For example, although the concave portion 2 is illustrated to be flat, alternatively, the concave portion 2 may have a round surface as illustrated in FIG. 1C. Furthermore, the inner portion 1 may also have a concave surface. When the substrate to be processed is deformed in the high-temperature process, the substrate to be processed may have a certain curvature. A curvature of the concave surface of the inner portion 1 may correspond to that of the substrate deformed in the high-temperature process, and thus a uniform heat transfer to the substrate may be achieved.

FIG. 2A schematically illustrates that the susceptor main body B and a rim 4 are separated from each other, according to an embodiment. FIG. 2B illustrates that the susceptor main body B and the rim 4 of FIG. 2A are coupled to each other. FIG. 2C is a cross-sectional view of the substrate supporting device taken along a line B-B′ of FIG. 2B.

Referring to FIGS. 2A to 2C, the substrate supporting device according to the present embodiment may include the susceptor main body B and the rim 4 for supporting a substrate. As illustrated in FIGS. 2B and 2C, the rim 4 may be accommodated on the concave portion 2. The substrate to be processed may be accommodated on the rim 4.

The rim 4 may be arranged between the inner portion 1 and the periphery portion 3 of the susceptor main body B. The rim 4 may be arranged spaced apart from the inner portion 1, and thus, even when the inner portion 1 or the rim 4 thermally expands in a horizontal direction at high temperature, the susceptor main body B may maintain the shape. For example, as illustrated in FIG. 2C, the first step portion 10 and the rim 4 may be arranged spaced apart from each other by a distance W.

The susceptor main body B and the rim 4 may be formed of different materials. For example, the susceptor main body B may be formed of a metal material such as aluminum or an alloy, or a material having a high thermal conductivity, to smoothly transfer heat to the substrate. The rim 4 may include an insulating body. In detail, the rim 4 may be formed of, for example, a material such as ceramic having a low thermal expansion rate to stably support the substrate at high temperature.

Although the rim 4 may be a donut shape having a rectangular section, the present disclosure is not limited thereto. For example, when the concave portion 2 has a round concave surface as illustrated in FIG. 1C, the rim 4 may have a shape of a convex lower surface as illustrated in FIG. 2D.

The susceptor main body B and/or the rim 4 may be adjusted and configured to have a size capable of accommodating a semiconductor substrate having a certain diameter, including a substrate of, for example, 150 mm, 200 mm, and 300 mm.

The rim 4 may be detachable from the susceptor main body B. In detail, an outer circumferential surface of the rim 4 and an inner circumferential surface of the concave portion 2 of the susceptor main body B are mechanically coupled to each other, and thus the rim 4 may be mounted in the susceptor main body B by, for example, a frictional force between the outer circumferential surface and the inner circumferential surface. In some embodiments, the rim 4 may be replaced with a rim having a different width and/or height.

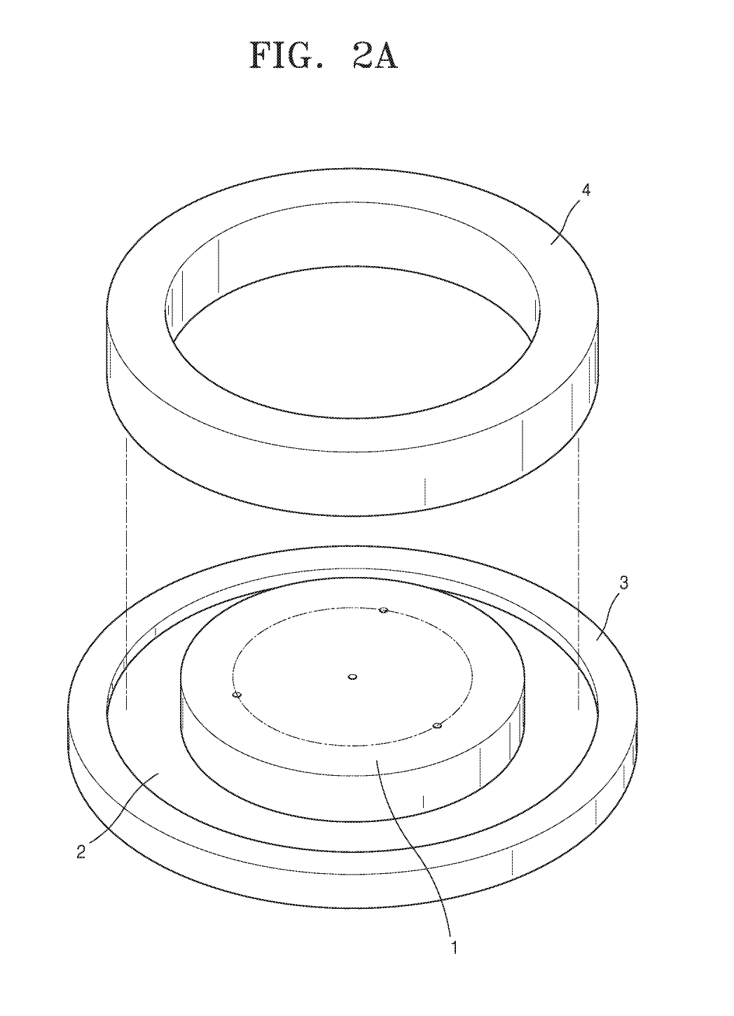

FIG. 3 is an enlarged view illustrating that the rim 4 is accommodated in the concave portion 2 of the susceptor main body B, according to an embodiment. FIG. 3 illustrates a state in which a substrate 5 is arranged in substrate supporting device.

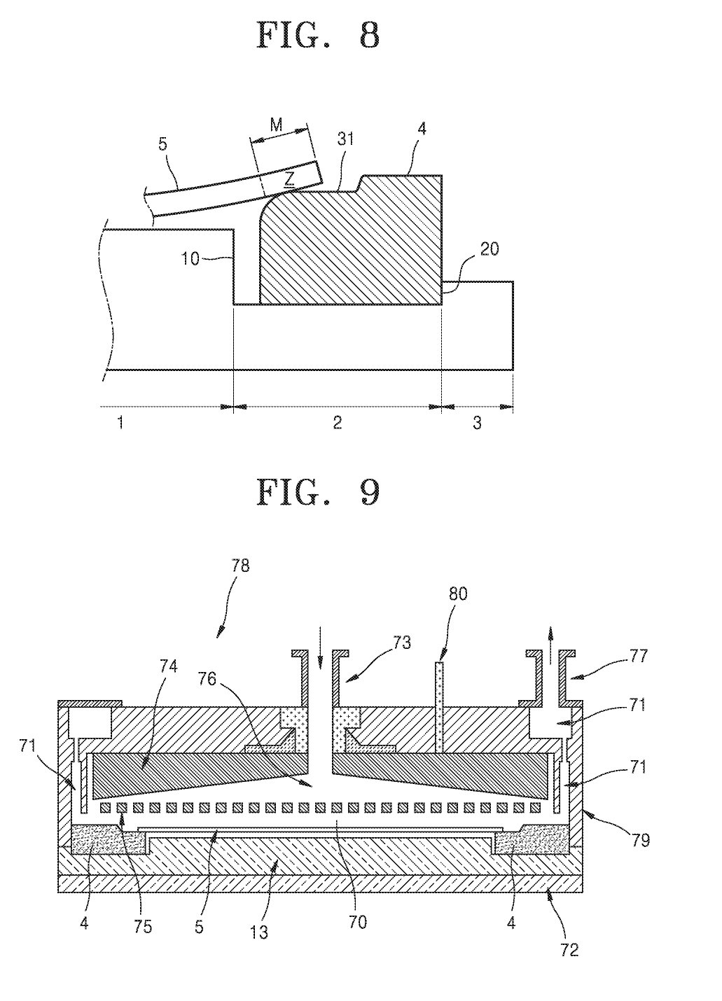

Referring to FIG. 3, as described above, the concave portion 2 and the inner portion 1 form the first step portion 10. The periphery portion 3 and the concave portion 2 form the second step portion 20. Furthermore, the rim 4 is arranged on the concave portion 2 between the first step portion 10 and the second step portion 20. As illustrated in FIG. 3, the rim 4 and the inner portion 1 are spaced apart by a certain distance W from each other, and thus the susceptor main body B may maintain the shape thereof even at high temperature. In order to perform a deposition process, the periphery portion 3 may form the reaction space by face-contacting and face-sealing the reactor wall of the reactor, which is described below with reference to FIG. 9.

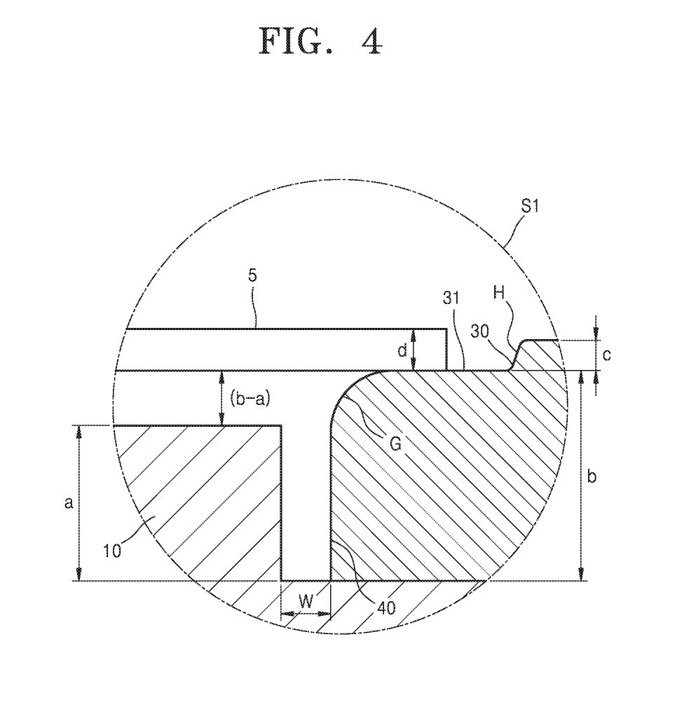

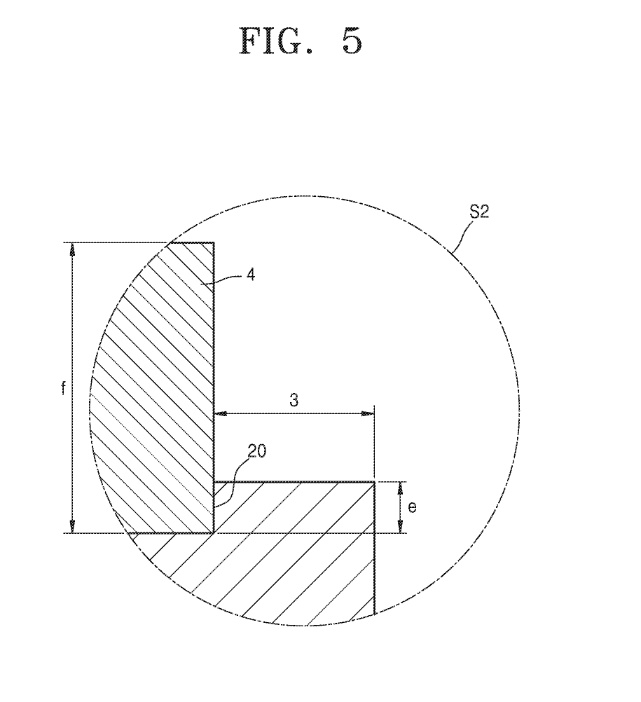

According to an embodiment, as illustrated in FIG. 3, the rim 4 may include a third step portion 30 formed toward the inner portion 1 on an inner side of an upper surface of the rim 4. In this case, the substrate 5 may be accommodated on the inner side of the third step portion 30. In some embodiments, the third step portion 30 of the rim 4 may further include a pad 31 on which the substrate 5 may be accommodated. According to an embodiment, as described later with reference to FIGS. 6 and 7, an edge portion, for example, an edge exclusion zone, of the substrate 5 is accommodated on the pad 31.

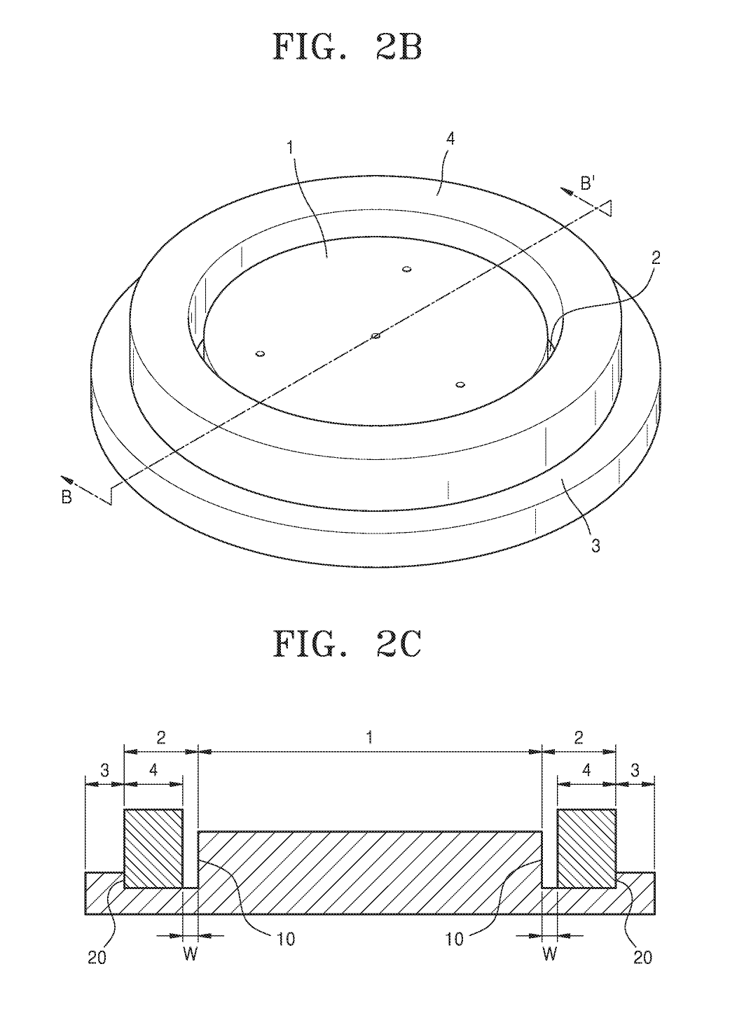

FIG. 4 is an enlarged cross-sectional view of an area S1 of FIG. 3, showing a mutual arrangement relationship of the susceptor main body B, the rim 4, and the substrate 5.

According to an embodiment, the height “a” of the inner portion 1, that is, the height “a” of the first step portion 10, may be set to be lower than the height from a lower surface of the rim 4 to the third step portion 30, that is, the height “b” of the pad 31. In the above structure, when the substrate 5 is accommodated on the pad 31, a lower surface of the substrate 5 and the inner portion 1 are spaced apart from each other. As the lower surface of the substrate 5 and the inner portion 1 are spaced apart from each other, a process gas may be prevented from intruding between a susceptor and a substrate during the high-temperature process for the following reason.

In the high-temperature process, a silicon substrate may generally warp downward toward a heating source, for example, the heater block, that is, in a direction toward the susceptor main body B. When the lower surface of the substrate and the substrate supporting device are not spaced apart from each other, if the substrate is deformed due to the high-temperature process, a gap is generated between the substrate and the substrate supporting device. The process gas may intrude into the gap, and the intruding process gas may be deposited on the rear surface of the substrate 5.

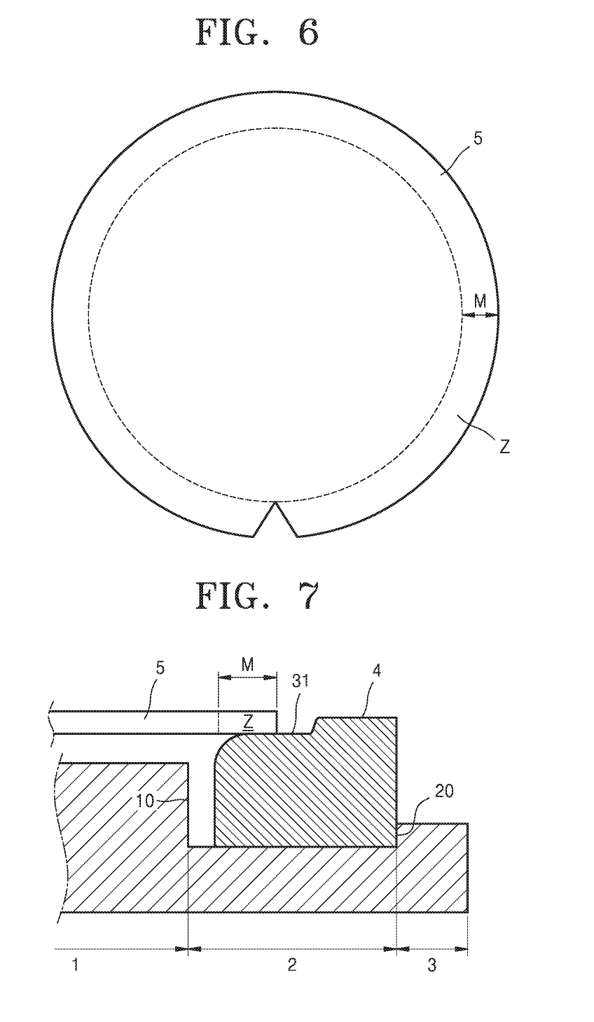

However, when the lower surface of the substrate 5 and the inner portion 1 are spaced apart from each other, as illustrated in FIG. 8, as the substrate 5 warps downward due to the high-temperature process, contact points are generated between the pad 31 and the substrate 5. In the present embodiment, the contact points may form a circular contact line along an upper surface of the rim 4. The contact line may serve as a barrier for preventing the intrusion of the process gas in the reactor into a space under the substrate 5 or between the substrate 5 and the inner portion 1.

In the following description, when a contact line is formed as two surfaces contact each other, it may be said that the two surfaces make a line contact. The contact line due to the line contact may have the shape, for example, a ring shape of a thin thickness corresponding to the substrate to be processed. Alternatively, the line contact may be generated at a corner portion, for example, the rim 4, of the substrate supporting device.

In order to facilitate heat radiation from a heating block (72 of FIG. 9) toward the substrate 5, a distance (b-a) between the substrate 5 and the inner portion 1 may be, for example, 0.1 mm to 0.5 mm. In an example, the distance (b-a) may be about 0.3 mm.

As described above, the susceptor main body B may be formed of a metal material such as aluminum or an alloy, or a material having a high thermal conductivity, to smoothly transfer heat to the substrate. Furthermore, the rim 4 may be formed of a material having a relatively low thermal deformation, for example, ceramic, to stably support the substrate at high temperature. As such, when the susceptor main body B has a larger deformation degree at high temperature than the substrate 5, since the substrate 5 and the inner portion 1, and the inner portion 1 and the rim 4, are spaced apart from each other and the rim 4 on which the substrate is accommodated is formed of a material having a relatively low thermal deformation, the high-temperature process may be stably performed without affecting the substrate.

The rim 4 may be formed of a material having a lower thermal deformation to keep the line contact with the substrate 5 at high temperature. For example, the rim 4 may have a thermal expansion rate suitable for keeping the line contact with the substrate 5 at a high temperature of over 300° C.

When an end portion G of the third step portion 30 is angled, as the substrate 5 warps downward, the substrate 5 may have a line contact with only the end portion G that is angled. The line contact having the narrow width may be inappropriate to prevent the intrusion of the process gas. Furthermore, since a pressure applied to the substrate 5 by the end portion G that is angled is strong, the substrate 5 may be damaged.

To prevent these problems, in another embodiment, the end portion G of the third step portion 30 may have a round shape. The round shape may be configured to form a line contact of a relatively large width with the substrate 5 that is deformed by the high-temperature process. If the end portion G of the third step portion 30 is in a rounded shape, a contact portion between the substrate 5 that warps and a contact portion of the end portion G becomes wider, and thus the pressure applied to the substrate 5 may be distributed to be further stable. In an embodiment, a curvature of the rounded shape may be that R=1.0.

In some embodiments, a portion having a line contact may be polished to have a low surface roughness. Accordingly, the surface roughness of the portion having a line contact in the substrate supporting device may be smaller than the surface roughness of the other portion of the substrate supporting device. Thus, close contact of a contact surface between the substrate 5 and the substrate supporting device may be improved. Accordingly, the process gas intruding between the substrate 5 and the substrate supporting device may be shielded.

In another embodiment, the third step portion 30 may have a structure H inclined toward the upper surface of the rim 4. The structure H may give a self-aligned function to have the substrate 5 accurately accommodated on the rim 4.

Furthermore, as illustrated in FIG. 4, the height “c” of the third step portion 30 may not be higher than the upper surface of the substrate 5. In other words, the height “c” of the third step portion 30 may be configured to be the same as or less than a thickness “d” of the substrate 5. Thus, the process gas supplied to the substrate 5 is guided to be smoothly exhausted through an exhaust channel (71 of FIG. 9) over the upper surface of the rim 4, and thus the reaction space may be prevented from being contaminated during a process.

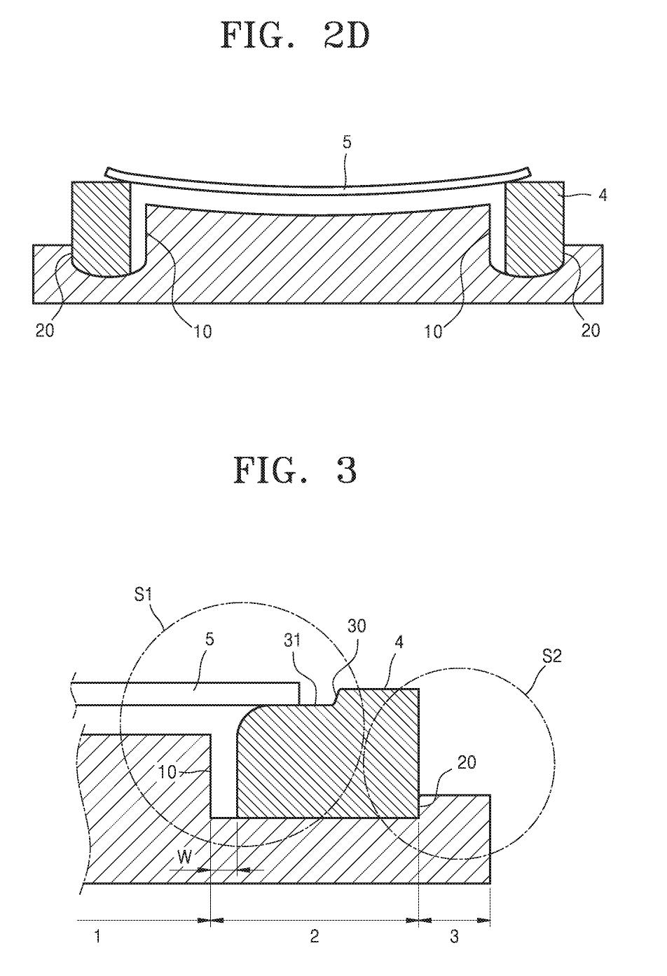

FIG. 5 is an enlarged cross-sectional view of an area S2 of FIG. 3, showing a mutual arrangement relationship between the rim 4 and the periphery portion 3.

As illustrated in FIG. 5, the height of the periphery portion 3 of the susceptor main body B, that is, the height “e” of the second step portion 20, may be configured to be lower than the height “f” of the rim 4. Accordingly, a contamination source, for example, contamination particles, generated as the process gas intrudes into the contact surface of a reactor wall (79 of FIG. 9) and the periphery portion 3, or particles remaining on the contact surface may be prevented from flowing backward toward a reaction space (70 of FIG. 9).

FIG. 6 schematically illustrates a substrate including an edge exclusion zone.

The substrate may include an edge exclusion zone Z at an edge thereof. Since the edge exclusion zone Z is not used as a die that is a device forming portion, the edge exclusion zone Z is distinguished from the other area of the substrate in that the uniformity of deposition is not needed. Typically, the edge exclusion zone Z is formed in an area that is about 2 mm to 3 mm away from the edge of the substrate. In the present specification, it is assumed that the edge exclusion zone Z of the substrate 5 has an interval M.

FIG. 7 illustrates that the substrate of FIG. 6 is accommodated on the pad 31, according to an embodiment.

In the present embodiment, the susceptor main body B and the rim 4 are formed of materials having different thermal conductivity, and a substrate S and the inner portion 1 are spaced apart from each other. Accordingly, in the substrate S, a portion contacting the rim 4 and a portion that does not contact the rim 4 may have different temperatures. Since the deposition process is generally sensitive to the temperature of the substrate S, irregularity in the temperature may affect the deposition process. Accordingly, as illustrated in FIG. 7, when the substrate 5 is accommodated on the rim 4, the rim 4 may contact the substrate 5 only in the edge exclusion zone Z. Accordingly, the temperature uniformity may be guaranteed in an area of the substrate 5 excluding the edge exclusion zone Z.

Furthermore, when the substrate 5 warps downward at high temperature, the rim 4 and the substrate 5 may form a line contact within the edge exclusion zone Z, that is, in an interval M from the edge of the substrate 5. Accordingly, as illustrated in FIG. 8, when the substrate 5 is deformed at high temperature, for example, 300° C. or more, unnecessary deposition may not be performed on the rear surface of the substrate excluding the edge exclusion zone Z.

In summary of the structures of FIGS. 7 and 8, the substrate supporting device according to embodiments may be described as follows.
The substrate supporting device may accommodate a substrate including the edge exclusion zone Z.
The substrate supporting device may include a support portion (not shown), and the support portion may be configured to have a line contact with the substrate that is deformed at a specific temperature, for example, 300° C.
(FIG. 7) When the substrate is accommodated on the support portion at a first temperature (low temperature), the edge exclusion zone Z of the substrate 5 may has a first contact, that is, a face contact, with the support portion. Due to the first contact, a first distance between a part of the edge exclusion zone Z and the support portion and a second distance between another part of the edge exclusion zone Z and the support portion may be substantially the same.
(FIG. 8) At a second temperature (high temperature) higher than the first temperature, the substrate 5 is deformed such that an area between the edge exclusion zone Z and a side (edge) of the substrate 5 has a second contact, that is, a line contact, with the support portion, for example, an angled portion or a rounded portion of the support portion. An area where the substrate 5 and the support portion contact each other due to the second contact may be smaller than an area where the substrate 5 and the support portion contact each other due to the first contact.

Due to the second contact, the first distance between a part of the edge exclusion zone Z and the support portion may be substantially different from the second distance between another part of the edge exclusion zone Z and the support portion. For example, the first distance between a portion of the edge exclusion zone Z where the second contact is formed and the support portion may be less than the second distance between a portion of the edge exclusion zone Z where the second contact is not formed and the support portion. In some embodiments, in order to improve the close contact between the substrate 5 and the support portion by reducing the first distance, a portion of the support portion that forms the second contact with the edge exclusion zone Z may be polished.

In an embodiment, an end portion of the pad 31 may be processed to have a non-right angle shape. For example, the end portion may be chamfered. In another example, the end portion may be processed to be round. Accordingly, the end portion of the pad 31 may have a line contact with the edge exclusion zone Z. Thus, unnecessary deposition may not be performed in an area other than the edge exclusion zone Z in the rear surface of the substrate 5, because the line contact between the non-right angle portion of the pad 31 and the substrate 5 serves as a barrier against the intrusion of the process gas in the high-temperature process.

In some embodiments, the length of the pad 31 and the curvature of the rounded portion may be adjusted to prevent the intrusion of the process gas into the rear surface of the substrate to be processed. For example, the length of the pad 31 may be equal to or less than the length M of the edge exclusion zone Z. In another embodiment, the rounded portion may be configured to have a curvature to prevent a movement or inclination of the substrate to be processed.

In detail, when the rounded portion has a too small curvature value, that is, too large radius of curvature, an area where a line contact between the rounded portion and the substrate to be processed is formed is too small, and thus the area may not properly serve as the barrier. In contrast, when the rounded portion has a too large curvature value, that is, a small radius of curvature, the substrate to be processed is deformed and thus the position of the substrate to be processed may be changed. Accordingly, the rounded portion may have a curvature value to achieve a sufficient contact area with the substrate to be processed and to reduce a movement or inclination of the substrate to be processed.

The above disclosure provides a plurality of embodiments of the substrate supporting device, for example, the susceptor, and a plurality of representative merits. For simplicity, a limited number of combinations of relevant characteristics only are described. However, it is understood that a certain example of the characteristics may be combined with another example of the characteristics. Furthermore, it is understood that the merits are non-restrictive and a particular merits is not, or is not requested to be, a characteristic of a particular embodiment.

FIG. 9 is a schematic cross-sectional view of a substrate processing apparatus including a substrate supporting device according to embodiments. Although an example of the substrate processing apparatus described in the present specification may include a deposition apparatus for a semiconductor or a display substrate, the present disclosure is not limited thereto. The substrate processing apparatus may be any apparatus needed to perform deposition of a material for forming a film, or may refer to an apparatus for uniformly supplying a source material for etching or polishing of a material. In the following description, for convenience of explanation, it is assumed that a substrate processing apparatus is a semiconductor deposition apparatus.

The substrate processing apparatus according to the present embodiment may include a reactor 78, a reactor wall 79, the susceptor main body B (13 of FIG. 9), and the substrate supporting device (susceptor portion) including the rim 4, a heater block 72, a gas inlet unit 73, a gas supply unit 75, and an exhaust unit 71.

Referring to FIG. 9, the susceptor portion is provided in the reactor 78. In the present embodiment, the susceptor portion may be, for example, the substrate supporting device illustrated in FIGS. 3 to 6. The susceptor main body B of the susceptor portion may include the inner portion 1, the periphery portion 3, and the concave portion 2 formed therebetween. The rim 4 is arranged on the concave portion 2.

The reactor 78 is a reactor in which an atomic layer deposition (ALD) or a chemical vapor deposition (CVD) process is performed. The reactor wall 79 and the periphery portion 3 of the susceptor main body B or 13 have a face-contact and face-sealing, thereby forming the reaction space 70. To prevent the backflow of a contamination source generated as the process gas intrudes into a contact surface of the reactor wall 79 and the periphery portion 3, toward the reaction space 70, the height of the rim 4 may be higher than the periphery portion 3.

The susceptor main body B for loading/unloading of the substrate 5 may be configured to move by being connected to a device (not shown) provided at one side of the susceptor main body B. For example, the susceptor main body B is connected to a device capable of ascending/descending the susceptor main body B, and an entrance through which the substrate 5 is input may be formed between the reactor wall 79 and the susceptor main body B or 13. In FIG. 9, the substrate 5 is loaded on the rim 4. According to an embodiment, the reactor 78 may have an upward exhaust structure, but the present disclosure is not limited thereto.

The heater block 72 may include a heat wire, and may supply heat to the susceptor main body B and the substrate 5. The gas supply unit may include a gas channel 74, a gas supply plate 75, and a gas flow channel 76. The gas flow channel 76 may be formed between the gas channel 74 and the gas supply plate 75. The process gas input through the gas inlet unit 73 may be supplied to the reaction space 70 and the substrate 5 through the gas flow channel 76 and the gas supply plate 75. The gas supply plate 75 may be a showerhead, and a base of the showerhead may include a plurality of gas supply holes formed to eject the process gas. The process gas supplied to the substrate 5 has a chemical reaction to the substrate 5 or between gases, and then may be deposited on the substrate 5.

The exhaust unit may include the exhaust channel 71 and an exhaust port 77. In the reaction space 70, a residual gas or a non-reactive gas remaining after the chemical reaction to the substrate 5 may be discharged to the outside through the exhaust channel 71 formed in the reactor wall 79, the exhaust port 77, and an exhaust pump (not shown). The exhaust channel 71 may be continuously formed along the reactor wall 79 in the reactor wall 79. A part of an upper portion of the exhaust channel 71 may be connected to the exhaust port 77.

The gas channel 74 and the gas supply plate 75 are formed of a metal material and are mechanically coupled to each other by a coupling unit such as a screw and may serve as an electrode during a plasma process. During a plasma process, a radio frequency (RF) power source may be electrically connected to the showerhead that functions as an electrode. In detail, an RF rod 80 connected to the RF power source may be connected to the gas channel 74 by penetrating through the reactor wall 79. In this case, the susceptor 13 may function as the other electrode. In some embodiments, for example, to prevent the plasma power applied during the plasma process from being discharged to the surroundings, an insulating body (not shown) is inserted between the RF rod 80 and the reactor wall 79, and/or between the gas channel 74 and the reactor wall 79, thereby forming a stack structure. The efficiency of the plasma process may be increased by preventing leakage of the plasma power.

Korean Patent Application No. 10-2016-0152239 describes in detail the embodiments of the gas inlet unit 73 and a gas exhaust unit of the reactor 78.

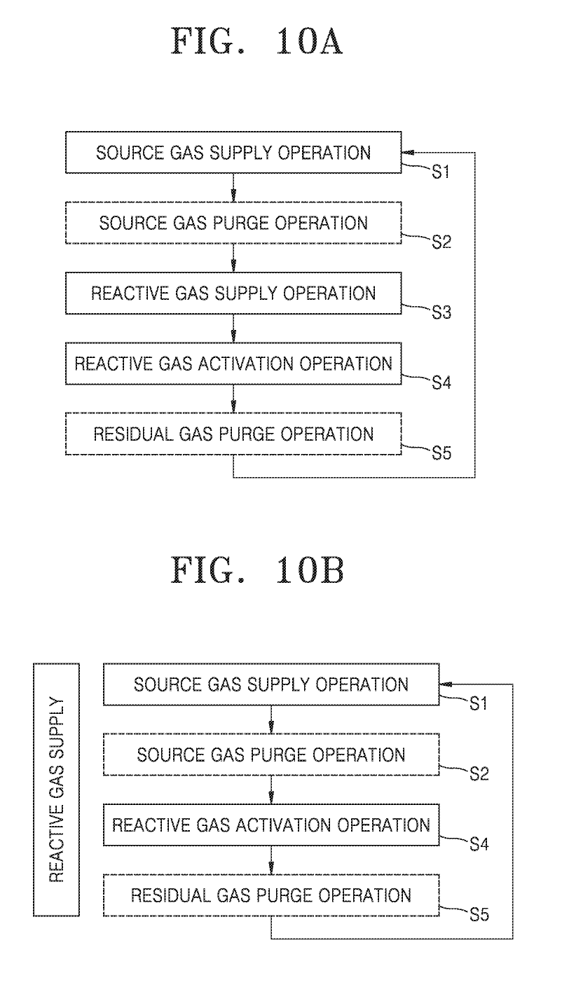

FIGS. 10A and 10B are flowcharts schematically showing substrate processing methods using the substrate processing apparatus, according to other embodiments. The substrate processing methods according to the present embodiments may be performed by using the substrate supporting device and the substrate processing apparatus according to the above-described embodiments. In particular, the substrate processing method is performed in a state in which the substrate 5 and the inner portion 1 of the susceptor 13 are spaced apart from each other. Redundant descriptions between the embodiments are omitted in the following description.

Referring to FIG. 10A, the substrate processing method may include a source gas supply operation S1, a reactive gas supply operation S3, and a reactive gas activation operation S4. As the operations are sequentially and repeatedly performed, a thin film may be deposited.

The substrate processing method may further include a source gas purge operation S2 to purge the source gas, between the source gas supply operation S1 and the reactive gas supply operation S3. Furthermore, the substrate processing method may further include a residual gas purge operation S5 to purge the residual gas, after the reactive gas activation operation S4. This is to supply another material to the reactor 78 after completely removing excessive material from the reactor 78 after one material is supplied to the reactor 78. Accordingly, the materials such as the source gas or the reactive gas may be prevented from meeting in a gaseous state.

The purge gas may be temporarily supplied to the reaction space during the operations S2 and/or the operation S5. In another embodiment, the purge gas may be continuously supplied to the reaction space during the source gas supply operation S1, the reactive gas supply operation S3, and the reactive gas activation operation S4.

Plasma may be supplied in the reactive gas activation operation S4. As the plasma is supplied, a high-density thin film may be obtained, and reactivity between sources (i.e., source and reactive gases) may be improved, thereby resulting in more selection of sources. Furthermore, the properties of a thin film may be improved, and thus a thin film may be deposited at a relatively low temperature.

When a reactant, for example, oxygen, which is activated only when the plasma is supplied and reacts to source molecules on the substrate 5, is used, the reactant may be supplied constantly into the reactor 78 throughout a basic cycle period. This is because the reactive gas serves as the purge gas when the plasma is not supplied. Accordingly, the reactive gas may be supplied, as illustrated in FIG. 10B, throughout a source gas supply operation S1, a source gas purge operation S2, a reactive gas activation operation S4, and a residual gas purge operation S5.

The substrate supporting devices according to the present embodiments may prevent the deposition of a film on the rear surface of the substrate 5, which is generated as the process gas intrudes into the rear surface of the substrate 5 in the high-temperature process. Accordingly, the substrate processing method may be performed, for example, even at a high temperature of 300° C. or more.

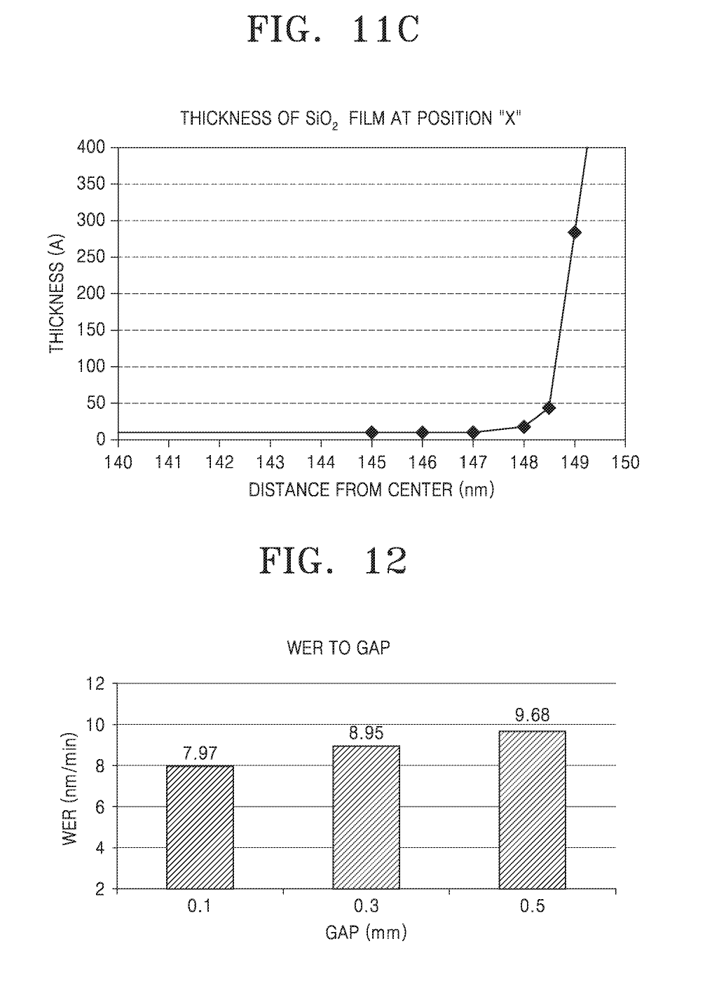

In additional embodiments, in the substrate processing method, wet etch resistance of a thin film may be controlled by adjusting an interval between the substrate 5 and the inner portion 1 of the susceptor, which is described later with reference to FIG. 12.

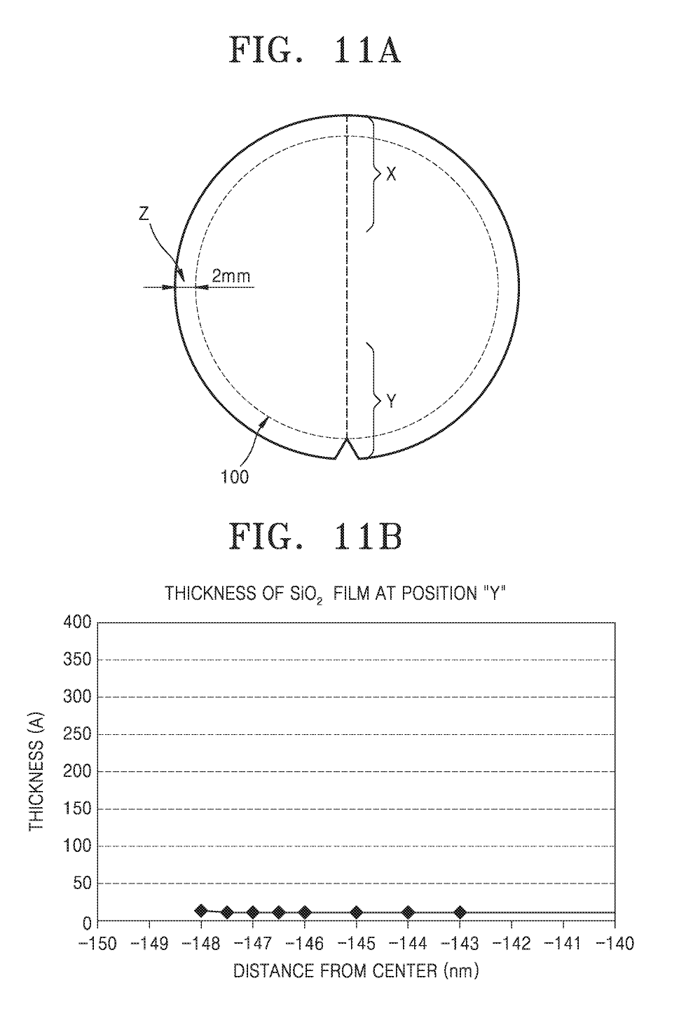

FIGS. 11A to 11C illustrate a thickness of a SiO₂ film deposited on the rear surface of the substrate 5 when a process is performed in a PEALD method by using the substrate processing apparatus of FIG. 9. In the present embodiment, an interval between the lower portion of the substrate 5 and the inner portion 1 of the susceptor is about 0.3 mm.

In FIG. 11A, the edge exclusion zone Z indicates an area where the substrate 5 and the rim 4 contact each other. A width M of the edge exclusion zone Z is about 2 mm. In the present embodiment, a line contact between the substrate 5 and the rim 4 is formed at a portion 100 indicated by a dashed line along the edge exclusion zone Z.

TABLE 1
Deposition conditions of SiO₂ film by PEALD

| | | |
|---|---|---|
| Temperature | Susceptor | 300° C. |
| (° C.) | Reactor | 150° C. to 180° C. |
| | wall | |
| Process | Source | 0.1 to 0.5, for example, 0.2 to 0.3 |
| time per | supply | |
| operation | Purge | 0.1 to 0.5, for example, 0.2 to 0.3 |
| (sec) | Plasma | 0.1 to 0.5, for example, 0.2 to 0.3 |
| | Purge | 0.1 to 0.5, for example, 0.2 to 0.3 |
| Gas flow | Carrier Ar | 500 to 1,500, for example, 900 to 1,100 sccm |
| rate | Purge Ar | 2,500 to 4,500, for example, 3,000 to |
| (sccm) | | 4,000 sccm |
| | Reactant | 400 to 1,000, for example, 600 to 800 sccm |

| | |
|---|---|
| Process pressure (Torr) | 2 Torr to 4 Torr, for example, 3 Torr |
| Si precursor | Precursor including silane base |
| Reactant | Gas including oxygen |

As shown in Table 1 above, according to an embodiment, during a process, the pressure of a reaction space is maintained at 3 Torr, the susceptor main body B contacting the heater block 72 maintains a temperature of about 300° C., and the reactor wall 79 maintains a temperature of about 150° C. to 180° C. In order to deposit a thin film, a basic cycle of a Si source gas supply operation a), a Si source purge operation b), a reactive gas activation operation c), and a purge operation d) is sequentially repeated. In particular, plasma is supplied in the reactive gas activation operation c).

In the present embodiment, the Si source may include a silane base. For example, the Si source may be at least one of TSA, (SiH₃)₃N; DSO, (SiH₃)₂; DSMA, (SiH₃)₂NMe; DSEA, (SiH₃)₂NEt; DSIPA, (SiH₃)₂N(iPr); DSTBA, (SiH₃)₂N(tBu); DEAS, SiH₃NEt₂; DIPAS, SiH₃N(iPr)₂; DTBAS, SiH₃N(tBu)₂; BDEAS, SiH₂(NEt₂)₂; BDMAS, SiH₂(NMe₂)₂; BTBAS, SiH₂(NHtBu)₂; BITS, SiH₂(NHSiMe3)₂; BEMAS, and SiH₂[N(Et)(Me)]₂. A gas including oxygen may be used as the reactant, and may be at least one of O₂, N₂O, and NO₂ or a compound thereof.

In the Si source gas supply operation a), the Si source gas is supplied into the reactor by a carrier gas Ar supplied to a source container that accommodates the source gas.

In the present embodiment in which a reactive gas including oxygen is used, the reactive gas is supplied throughout the basic cycle period. Oxygen that is activated only when plasma is supplied may react to Si source molecules on the substrate. When the plasma is not supplied, the oxygen may serve as the purge gas. Accordingly, the reactive gas including oxygen is excited in the reactive gas activation operation c), in which plasma is supplied, to react to a silicon source on the substrate, and continuously purges the reactor with the purge gas Ar in the operations a), b), and d) during which no plasma is supplied.

A flow rate of the gas may be appropriately adjusted according to desired thin film uniformity around the substrate 5.

FIG. 11B shows a change in the deposition thickness of a SiO₂ film deposited on a portion Y when the portion Y is scanned inwardly by about 10 mm from a lower end of the rear surface of the substrate in FIG. 11A. FIG. 11C shows a change in the deposition thickness of a SiO₂ film deposited on a portion X when the portion X is scanned inwardly by about 10 mm from an upper end of the rear surface of the substrate in FIG. 11A.

In the graphs of FIGS. 11B and 11C, horizontal axes denote a distance from the center of the rear surface of the substrate when the diameter of the substrate is about 300 mm. In other words, in the horizontal axis of FIG. 11B, a portion from −150 mm to −148 mm denotes a portion 148 mm to 150 mm downward away from the center of the substrate, that is, a notch area (the edge exclusion zone Z of the portion Y). Likewise, in the horizontal axis of FIG. 11C, a portion from 148 mm to 150 mm denotes a portion 148 mm to 150 mm upward away from the center of the substrate, that is, the edge exclusion zone Z of the portion X. The vertical axes of the graphs denote the thickness of a deposited thin film.

Comparing FIG. 11A and FIG. 11C, it may be seen that, while a thin film is deposited in an area (length of 2 mm) from the edge of the substrate 5 to the portion 100 where a line contact of the substrate 5 and the rim 4 is formed, that is, in the edge exclusion zone Z, the deposition thickness is greatly decreased in an area from the portion 100 to the inside of the substrate 5. This is because the substrate 5 is arranged such that process gases to be deposited on the rear surface of the substrate 5 are deposited only in the edge exclusion zone Z of the substrate 5.

In FIG. 11B, the deposition thickness is not measured in a portion of −150 mm to −148 mm in the horizontal axis because the portion of −150 mm to −148 mm in the horizontal axis corresponds to the notch portion that is a non-deposition area of the substrate 5. Although the substrate 5 includes the notch, as an inner end portion of the notch forms a line contact with the rim 4, the process gas may not be intrude into the rear portion of the substrate 5 through the notch. It may be seen that deposition is hardly formed in a portion of −148 mm to −140 mm in the horizontal axis of FIG. 11B.

FIG. 12 is a graph showing a change in a wet etch ratio (WER) according to a distance between the inner portion 1 of the susceptor and the substrate 5 when a SiO₂ film is deposited on the substrate 5 by a PEALD method using the susceptor at a reactor temperature of about 300° C. by using the substrate processing apparatus of FIG. 9, according to an embodiment. The other conditions of the deposition process are the same as the process conditions of the embodiment of FIGS. 11A to 11C. Wet etch is performed by using a diluted hydrofluoric acid (dHF) solution.

In the graph of FIG. 12, the horizontal axis denotes a distance (b-a in FIG. 4) between the inner portion 1 of the susceptor and the substrate 5. The vertical axis denotes an average value of WER (nm/min) of the SiO₂ film deposited at the center portion and the edge portion of the substrate 5.

Referring to the graph of FIG. 12, it may be seen that WER increases as a distance between the inner portion 1 of the susceptor and the substrate 5 increases.

When the etch speed is too fast, materials to be removed after etch may not be properly moved, and thus an etched surface may be rough. Thus, the etch may be controlled at an appropriate speed. A desired WER may be implemented by appropriately adjusting the interval between the inner portion 1 of the susceptor and the substrate 5 according to the embodiments.

In addition, by adjusting the interval between the inner portion 1 of the susceptor and the substrate 5, the properties of a thin film other than WER may be controlled. For example, the interval between the inner portion 1 of the susceptor and the substrate 5 may affect density of plasma applied during the deposition process.

Although in the present specification a standard silicon wafer is described as an example, the substrate supporting device according to the present embodiment may be used to support other types of substrates such as glass that may undergo a process such as CVD, physical vapor deposition (PVD), etching, annealing, impurity diffusion, photolithography, etc.

As described above, according to the above-described embodiments, the substrate supporting device and the substrate processing apparatus including the same may prevent the film deposition on the rear surface of the substrate from being generated as the process gas intrudes into the rear surface of the substrate even in a high-temperature process. Furthermore, according to the embodiments, since the inner portion of the susceptor main body and the substrate are spaced apart a certain distance from each other, a process may be stably performed on the substrate regardless of the deformation of the substrate and the susceptor main body that may be generated in the high-temperature process. Furthermore, according to the above embodiments, as the distance between the inner portion of the susceptor main body and the substrate is appropriately adjusted, the properties of a thin film, for example, WER in a subsequent etch, may be selectively implemented.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope as defined by the following claims.

What is claimed is:

1. A substrate supporting device comprising:
an inner portion;
a periphery portion; and
a concave portion formed between the inner portion and the periphery portion,
wherein a first step portion is formed between the inner portion and the concave portion, and
wherein a second step portion is formed between the periphery portion and the concave portion.

2. The substrate supporting device of claim 1, further comprising a rim arranged in the concave portion,
wherein the rim is arranged between the first step portion and the second step portion.

3. The substrate supporting device of claim 2, wherein the rim comprises a third step portion formed on an upper surface of the rim toward the inner portion.

4. The substrate supporting device of claim 3, wherein the third step portion comprises a pad, and a substrate is accommodated on the pad.

5. The substrate supporting device of claim 4, wherein a height of the first step portion is lower than a height of the pad such that a lower surface of the substrate is space apart from the inner portion.

6. The substrate supporting device of claim 5, wherein a height of the third step portion is lower than an upper surface of the substrate.

7. The substrate supporting device of claim 2, wherein the first step portion and the rim are spaced apart from each other.

8. The substrate supporting device of claim 2, wherein a height of the second step portion is lower than a height of the rim.

9. The substrate supporting device of claim 2, wherein the rim comprises an insulation body.

10. The substrate supporting device of claim 2, wherein the substrate is accommodated on the rim,
the substrate is deformed at a specific temperature to have a certain curvature toward the inner portion, and
a deformed substrate has a line contact with the rim.

11. The substrate supporting device of claim 10, wherein a portion of the rim forming a line contact has a non-right angle shape.

12. A substrate supporting device for accommodating a substrate including an edge exclusion zone, the substrate support device comprising a support portion configured to have a line contact with the edge exclusion zone of the substrate deformed at a specific temperature.

13. The substrate supporting device of claim 12, wherein, when the substrate is accommodated on the support portion at a first temperature, the edge exclusion zone has a first contact with the support portion.

14. The substrate supporting device of claim 13, wherein the substrate is deformed at a second temperature higher than the first temperature such that an area between the edge exclusion zone and a side of the substrate has a second contact with the support portion, and
an area where the substrate and the support portion contact each other by the second contact is smaller than an area where the substrate and the support portion contact each other by the first contact.

15. The substrate supporting device of claim 12, wherein a surface roughness of a portion of the substrate supporting device forming the line contact is less than a surface roughness of the other portion of the substrate supporting device.

16. The substrate supporting device of claim 12, further comprising a heating portion arranged spaced apart from the substrate,
wherein properties of a thin film formed on the substrate are controlled according to a distance between the substrate and the heating portion.

17. A substrate processing apparatus comprising:
a reactor wall;
a substrate supporting device;
a heater block;
a gas inlet unit;
a gas supply unit; and
an exhaust unit,
wherein the reactor wall and the substrate supporting device have a face contact forming a reaction space, and
wherein the substrate supporting device comprises a susceptor main body and a rim.

18. The substrate processing apparatus of claim 17, wherein the susceptor main body comprises an inner portion, a periphery portion, and a concave portion formed between the inner portion and the periphery portion, and
the rim is arranged in the concave portion.

19. The substrate processing apparatus of claim 17, wherein a first space is formed between the substrate and the inner portion, and
a second space is formed between the inner portion and the rim.

20. A substrate processing method for depositing a thin film, the method comprising:
supplying a source gas;
supplying a reactive gas; and
activating the reactive gas, which are repeated to deposit the thin film,
wherein a substrate and a susceptor are spaced apart from each other, and
wherein properties of the thin film are controlled according to an interval between a main body of the susceptor and the substrate.
